(19) United States
(12) Patent Application Publication
(10) Pub. No.: US 2014/0239360 A1
(43) Pub. Date: Aug. 28, 2014

(54) SEMICONDUCTOR DEVICE AND A METHOD OF MANUFACTURING THE SAME, AND SOLID-STATE IMAGE PICKUP DEVICE USING THE SAME

(71) Applicant: Sony Corporation, Tokyo (JP)

(72) Inventor: Ryosuke Nakamura, Kanagawa (JP)

(73) Assignee: Sony Corporation, Tokyo (JP)

(21) Appl. No.: 14/268,431

(22) Filed: May 2, 2014

Related U.S. Application Data
(62) Division of application No. 12/604,508, filed on Oct. 23, 2009.

(30) Foreign Application Priority Data
Oct. 30, 2008 (JP) 2008-279474

(51) Int. Cl. H01L 29/78; H01L 27/146; H01L 29/66

(52) U.S. Cl. CPC H01L 29/7835; H01L 29/66492; H01L 27/14612
USPC 257/290; 257/408; 438/286

(57) ABSTRACT

A semiconductor device, including: a gate electrode formed on a semiconductor substrate through a gate insulating film; an extension region formed in the semiconductor substrate on a source side of the gate electrode; a source region formed in the semiconductor substrate on the source side of the gate electrode through the extension region; an LDD region formed in the semiconductor substrate on a drain side of the gate electrode; and a drain region formed in the semiconductor substrate on the drain side of the gate electrode through the LDD region; wherein the extension region is formed at a higher concentration than that of the LDD region so as to be shallower than the LDD region.

### RELATED APPLICATION DATA

This application is a division of U.S. patent application Ser. No. 12/604,508 filed Oct. 23, 2009, the entirety of which is incorporated herein by reference to the extent permitted by law. The present application claims the benefit of priority to Japanese Patent Application No. JP 2008-279474 filed on Oct. 30, 2008 in the Japan Patent Office, the entirety of which is incorporated by reference herein to the extent permitted by law.

### BACKGROUND OF THE INVENTION

1. Field of the Invention

The present invention relates to a semiconductor device and a method of manufacturing the same, and a solid-state image pickup device using the same.

2. Description of the Related Art

A source follower circuit used in an output portion of a solid-state image pickup element is a circuit for amplifying a resulting signal from a pixel, and driving a load in a subsequent stage. In general, a CMOS (Complementary Metal Oxide Semiconductor) transistor is used in the source follower circuit. Thus, the CMOS transistor operates in such a way that a source returns a signal Vout so as to follow a signal Vin supplied to a gate. When the performance of the CMOS transistor is high, it can be said that the CMOS transistor has a high performance in terms of the output circuit as well. A gain, a hot carrier current, a random noise, and the like of the source follower circuit are given as concrete characteristic items. The way of thinking about the source follower circuit is generally defined as the gain=gm/(gm+gmb+gds) where gm represents a mutual conductance, gmb represents a mutual conductance of a back gate, and gds represents a mutual conductance between a source and a drain. In addition, in the case of a solid-state image pickup device, a fringe capacitance of a gate is also given as one of the concrete characteristic items.

With regard to the measures taken to cope with the promotion of the high performance of the CMOS transistor by the existing technique, a Lightly Doped Drain (LDD) structure is used for the purpose of reducing the hot carrier current. With regard to the basic structure, an impurity region composed of the LDD region and a densely doped (S/D) region takes a symmetrical structure. This technique, for example, is disclosed in Japanese Patent Application No. 2006-187045.

However, with the LDD structure described above, a large parasitic resistance is generated and thus the characteristics of the mutual conductance gm is deteriorated because diffusion layer such as a source region and a drain region are each formed at a low impurity concentration.

A structure with which a diffusion layer on a source side is deeply formed at a high impurity concentration to reduce the parasitic resistance, thereby aiming at improving the mutual conductance gm is known as a structure with which it is tried to reduce the parasitic resistance described above. This technique, for example, is disclosed in Japanese Laid-Open Patent Application No. Hei 10-22226.

The two kinds of techniques, that is, the symmetrical LDD structure and the asymmetrical structure having the diffusion layer on the source side of which is deeply formed at the high impurity concentration are established as the existing techniques in the manner as described above.

Some positive results are achieved even with the existing technique in the characteristic improvements such as the improvement in the gain, the reduction in hot carrier current, and the reduction in random noise in the source follower circuit. In particular, the LDD structure on the drain side is introduced to most the devices for the purpose of reducing the hot carrier current. However, the asymmetrical deep diffusion layer structure on the source side is not introduced to the devices so much because the improvement in the gain of the source follower circuit may not be obtained as expected. As the reason for this, it is thought that the deep diffusion layer on the source side makes the short channel effect of the transistor worse to increase the mutual conductance gds between the source and the drain. That is to say, the reason for this is because the mutual conductance gds between the source and the drain is made worse, thereby reducing the gain of the source follower circuit.

In addition, although attention is paid to the gain of the source follower circuit, the characteristic vales of the mutual conductance gm, the mutual conductance gmb of the back gate, and the mutual conductance gds between the source and the drain show a trade-off relationship. As a result, the promotion of the high performance peaks out, which becomes a problem.

### SUMMARY OF THE INVENTION

A problem to be solved by embodiments of the present invention is that the deep diffusion layer on the source side makes the short channel effect of the transistor worse to increase the mutual conductance gds between the source and the drain, and thus the improvement in the gain of the source follower circuit may not be obtained as expected.

The embodiments of the present invention have been made in order to solve the problem described above, and it is therefore desirable to provide a semiconductor device in which reduction in mutual conductance (hereinafter referred to as “gm” for short) is suppressed, and a mutual conductance between a source and a drain (hereinafter referred to as “gds” for short) and a mutual conductance of a back gate (hereinafter referred to as “gmb” for short) are maintained, thereby making promotion of a high performance of a MOS transistor possible and a method of manufacturing the same, and a solid-state image pickup device using the same.

In order to attain the desire described above, according to an embodiment of the present invention, there is provided a semiconductor device including: a gate electrode formed on a semiconductor substrate through a gate insulating film; an extension region formed in the semiconductor substrate on a source side of the gate electrode; a source region formed in the semiconductor substrate on the source side of the gate electrode through the extension region; an LDD region formed in the semiconductor substrate on a drain side of the gate electrode; and a drain region formed in the semiconductor substrate on the drain side of the gate electrode through the LDD region; in which the extension region is formed at a higher concentration than that of the LDD region so as to be shallower than the LDD region.

In the semiconductor device according to the embodiment of the present invention, the hot carrier current is suppressed by the LDD region, the short channel effect is suppressed by the extension region, and gds between the source region and the drain region is improved. In addition, a channel region can be formed lightly in impurity concentration and thus gm is prevented from being made worse because the short channel effect is suppressed. In addition, since the extension region can be formed at the higher impurity concentration than that of the LDD region, the parasitic resistance is hardly increased, and thus the reduction in gm is less.

According to another embodiment of the present invention, there is provided a method of manufacturing a semiconductor device including the steps of: forming a gate electrode on a semiconductor substrate through a gate insulating film; forming an LDD region in the semiconductor substrate on a drain side of the gate electrode; forming an extension region in the semiconductor substrate on a source side of the gate electrode; forming a source region in the semiconductor substrate on the source side of the gate electrode through the extension region, and forming a drain region in the semiconductor substrate on the drain side of the gate electrode through the LDD region; and forming the extension region at a higher concentration than that of the LDD region so as to be shallower than the LDD region.

In the method of manufacturing a semiconductor device according to another embodiment of the present invention, the hot carrier current is suppressed by forming the LDD region, the short channel effect is suppressed by forming the extension region, and gds between the source region and the drain region is improved. In addition, a channel region can be formed lightly in impurity concentration and gm is prevented from being made worse because the short channel effect is suppressed. In addition, since the extension region can be formed at the higher impurity concentration than that of the LDD region, the parasitic resistance is hardly increased, and thus the reduction in gm is less.

According to still another embodiment of the present invention, there is provided a solid-state image pickup device including: a photoelectric conversion portion for subjecting an incident light to photoelectric conversion, thereby obtaining signal electric charges; and a source follower circuit for converting the signal charges read out from the photoelectric conversion portion into a voltage, thereby outputting the resulting voltage; at least one transistor of the source follower circuit including: a gate electrode formed on a semiconductor substrate through a gate insulating film; an extension region formed in the semiconductor substrate on a source side of the gate electrode; a source region formed in the semiconductor substrate on the source side of the gate electrode through the extension region; an LDD region formed in the semiconductor substrate on a drain side of the gate electrode; and a drain region formed in the semiconductor substrate on the drain side of the gate electrode through the LDD region; in which the extension region is formed at a higher concentration than that of the LDD region so as to be shallower than the LDD region.

In the solid-state image pickup device according to the still another embodiment of the present invention, the high-performance semiconductor device in which the reduction in gm is less, and thus gds and gmb are maintained is used in the source follower circuit.

According to the semiconductor device of the embodiments of the present invention, there is obtained an advantage that the high performance of the MOS transistor can be promoted because the reduction in gm showing the trade-off relationship with gds and gmb can be suppressed, and thus gds and gmb can be maintained. Therefore, using the semiconductor device of the embodiments of the present invention in the source follower circuit makes it possible to improve the gain of the source follower circuit.

According to the method of manufacturing a semiconductor device of the embodiments of the present invention, there is obtained an advantage that the high performance of the MOS transistor can be promoted because the reduction in gm showing the trade-off relationship with gds and gmb can be suppressed, and thus gds and gmb can be maintained. Therefore, using the semiconductor device of the embodiments of the present invention in the source follower circuit makes it possible to improve the gain of the source follower circuit.

According to the solid-state image pickup device of the embodiments of the present invention, there is obtained an advantage that the high performance of the output circuit can be promoted because the high-performance MOS transistor can be used in the source follower circuit, and thus the gain of the source follower circuit can be improved.

### BRIEF DESCRIPTION OF THE DRAWINGS

FIG. 1 is a schematic cross sectional view showing a structure of a first example of a semiconductor device according to a first embodiment of the present invention;

FIGS. 2A and 2B are respectively schematic cross sectional views explaining a diffusion layer depth Xjs of an extension region, and a diffusion layer depth Xjd of an LDD region;

FIG. 3 is a graph explaining a relationship between a ratio of Xjs/Xjd, and a gain of a source follower circuit;

FIG. 4 is a schematic cross sectional view showing a structure of a second example of the semiconductor device according to the first embodiment of the present invention;

FIG. 5 is a schematic cross sectional view showing a structure of a third example of the semiconductor device according to the first embodiment of the present invention;

FIGS. 6A to 6F are respectively schematic cross sectional views showing manufacturing processes in a first example of a method of manufacturing the semiconductor device according to a second embodiment of the present invention;

FIGS. 7A to 7F are respectively schematic cross sectional views showing manufacturing processes in a second example of the method of manufacturing the semiconductor device according to the second embodiment of the present invention;

FIGS. 8A to 8G are respectively schematic cross sectional views showing manufacturing processes in a third example of the method of manufacturing the semiconductor device according to the second embodiment of the present invention; and

FIG. 9 is a schematic circuit diagram showing a configuration of an example of a solid-state image pickup device according to a third embodiment of the present invention.

### DETAILED DESCRIPTION OF THE PREFERRED EMBODIMENTS

Preferred embodiments of the present invention will be described in detail hereinafter with reference to the accompanying drawings.

### 1. First Embodiment

A semiconductor device according to a first embodiment of the present invention includes: a gate electrode formed on a semiconductor substrate through a gate insulating film; an extension region formed in the semiconductor substrate on a source side of the gate electrode; a source region formed in the semiconductor substrate on the source side of the gate electrode through the extension region; an LDD region formed in the semiconductor substrate on a drain side of the gate electrode; and a drain region formed in the semiconductor substrate on the drain side of the gate electrode through the LDD region; in which the extension region is formed at a higher concentration than that of the LDD region so as to be shallower than the LDD region.

### First Example

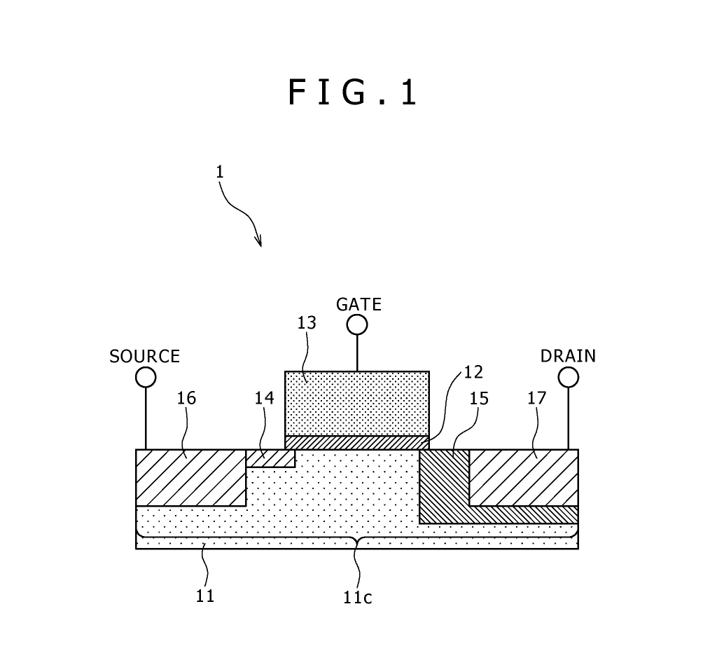

A first example of the semiconductor device according to the first embodiment of the present invention will be described in detail hereinafter with reference to a schematic structural cross sectional view of FIG. 1.

As shown in FIG. 1, a channel region 11c is formed in the semiconductor substrate 11. In the case of an NMOS transistor, for example, a semiconductor substrate 11 is doped with either boron or indium at an impurity concentration of 1×10¹⁹/cm³ or less, thereby forming the channel region 11c. Preferably, indium having a smaller diffusion coefficient is used in the doping process.

On the other hand, in the case of a PMOS transistor, for example, the semiconductor substrate 11 is doped with either arsenic or phosphorus at an impurity concentration of 1×10¹⁹/cm³ or less, thereby forming the channel region 11c. Preferably, arsenic having a smaller diffusion coefficient is used in the doping process.

A gate electrode 13 is formed on the semiconductor substrate 11 through a gate insulating film 12. A silicon semiconductor substrate, for example, is used as the semiconductor substrate 11. Alternatively, a Silicon on Insulator (SOI) substrate or the like may be used as the semiconductor substrate 11.

An extension region 14 is formed in a portion of the semiconductor substrate 11 on the source side of the gate electrode 13.

In the case of the NMOS transistor, the extension region 14 is formed in the form of an impurity region, for example, formed by diffusing thereinto either arsenic or phosphorus. For example, either an arsenic concentration or a phosphorus concentration in the extension region 14 is in the range of about 1×10¹⁸/cm³ to about 5×10²¹/cm³.

On the other hand, in the case of the PMOS transistor, the extension region 14 is formed in the form of an impurity region, for example, formed by diffusing thereinto boron (the extension region 14 is doped with boron in the form of boron difluoride). For example, a boron concentration in the extension region 14 is in the range of about 1×10¹⁸/cm³ to about 5×10²¹/cm³.

A source region 16 is formed in a portion of the semiconductor substrate 11 on the source side of the gate electrode 13 through the extension region 14.

In the case of the NMOS transistor, the source region 16 is formed in the form of an impurity region, for example, formed by diffusing thereinto either arsenic or phosphorus. For example, either an arsenic concentration or a phosphorus concentration in the source region 16 is in the range of about 1×10¹⁸/cm³ to about 5×10²¹/cm³.

Arsenic is preferably used as the impurity forming the extension region 14. The reason for this is because the impurity having a smaller diffusion coefficient is preferably used and thus arsenic having a smaller diffusion coefficient than that of phosphorus is preferably used since the extension region 14 is shallowly formed.

On the other hand, in the case of the PMOS transistor, the source region 16 is formed in the form of an impurity region, for example, formed by diffusing thereinto boron (the source region 16 is doped with boron in the form of boron difluoride). For example, a boron concentration in the source region 16 is in the range of about 1×10¹⁸/cm³ to about 5×10²¹/cm³.

In addition, an LDD region 15 is formed in a portion of the semiconductor substrate 11 on a drain side of the gate electrode 13.

In the case of the NMOS transistor, the LDD region 15 is formed in the form of an impurity region, for example, formed by diffusing thereinto either arsenic or phosphorus. For example, phosphorus is preferably used and a phosphorus concentration is lower than that of the extension region 14. Thus, the phosphorus concentration in the LDD region 15, for example, is selected from the range of 5×10¹⁶ /cm³ to 1×10²⁰/cm³.

The reason that phosphorus is used as the impurity forming the LDD region 15 is because the effect for weakening an electric field is larger in phosphorus than in arsenic.

On the other hand, in the case of the PMOS transistor, the LDD region 15 is formed in the form of an impurity region, for example, formed by diffusing thereinto boron (the LDD region 15 is doped with boron in the form of boron difluoride). A boron concentration in the LDD region 15 is lower than that in the extension region 14, and, for example, is selected from the range of 1×10¹⁷/cm³ to 5×10²⁰/cm³.

A drain region 17 is formed in a portion of the semiconductor substrate 11 on the drain side of the gate electrode 13 through the LDD region 15.

In the case of the NMOS transistor, the drain region 17 is formed in the form of an impurity region, for example, formed by diffusing thereinto either arsenic or phosphorus. For example, either an arsenic concentration or a phosphorus concentration in the drain region 17 is in the range of about 1×10¹⁸/cm³ to about 5×10²¹/cm³.

On the other hand, in the case of the PMOS transistor, the drain region 17 is formed in the form of an impurity region, for example, formed by diffusing thereinto boron (the drain region 17 is doped with boron in the form of boron difluoride). For example, a boron concentration in the drain region 17 is in the range of about 1×10¹⁸/cm³ to about 5×10²¹/cm³.

The semiconductor device 1 of the first example is structured in the form of the MOS transistor in the manner as described above.

In the semiconductor device 1 of the first example described above, a hot carrier current is suppressed by the LDD region 15, a short channel effect is suppressed by the extension region 14 shallower than the LDD region 15, and gds between the source region 16 and the drain region 17 is improved. In addition, since the short channel effect is suppressed, the channel region can be formed at the low impurity concentration, and thus gmb can be prevented from being made worse. In addition, since the extension region 14 is formed at the higher impurity concentration than that of the LDD region 15, a parasitic resistance is hardly increased and thus reduction in gm is also less.

Therefore, there is obtained an advantage that since the reduction in gm showing the trade-off relationship with gds and gmb is less and thus gds and gmb can be maintained, the high performance promotion of the MOS transistor can be realized. As a result, using the semiconductor device 1 of the first example described above in the source follower circuit makes it possible to enhance the gain of the source follower circuit.

For the backing-up for making it possible to enhance the gain of the source follower circuit described above, a TCAD simulation was carried out.

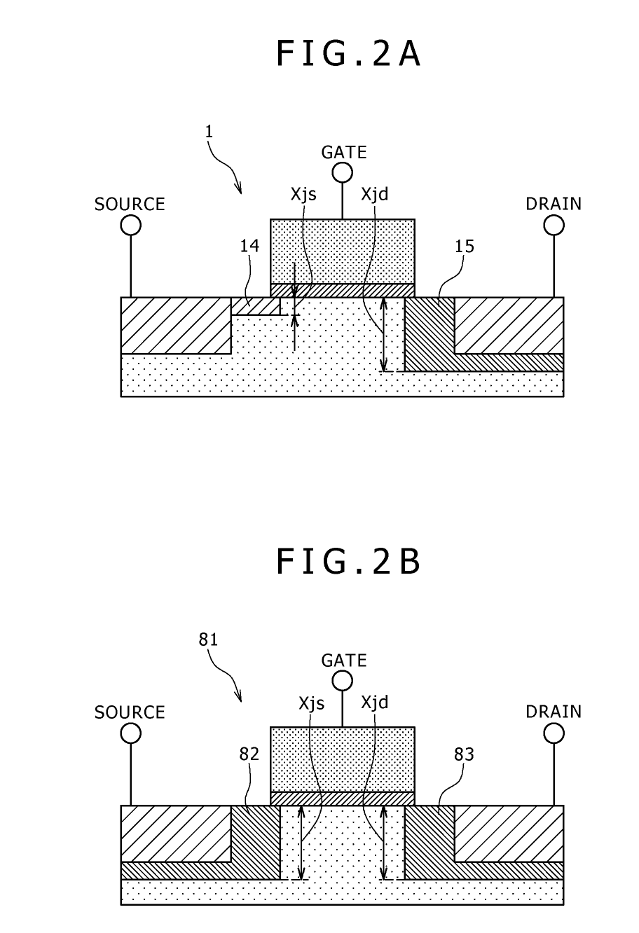

As shown in FIG. 2A, a diffusion layer depth of the extension region 14 of the semiconductor device 1 described above is set as Xjs, and a diffusion layer depth of the LDD region 15 described above is set as Xjd. In addition, as shown in FIG. 2B, a diffusion layer depth of an LDD region 82 on a source side of an existing semiconductor device 81 is set as Xjs, and a diffusion layer depth of an LDD region 83 on a drain side thereof is set as Xjd.

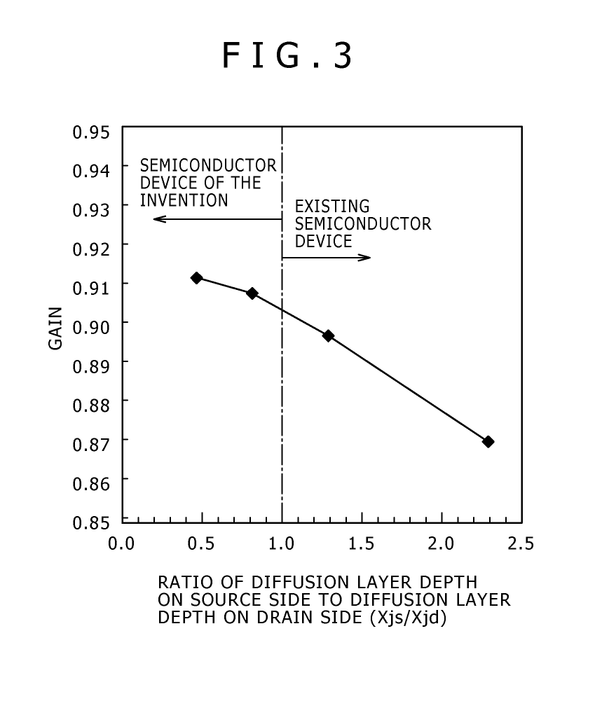

Here, FIG. 3 shows a relationship between a ratio of Xjs to Xjd, and a gain of a source follower circuit. In the figure, an axis of ordinate indicates the gain, and an axis of abscissa indicates the ratio in the diffusion layer depth Xj represented by Xjs/Xjd.

As shown in FIG. 3, in the case where the depth of the LDD region on the source side, and the depth of the LDD region on the drain side in the existing semiconductor device are equal to each other, that is, the case where the ratio in the diffusion layer depth Xj is 1 is set as a reference, it is understood that the gain of the source follower circuit is enhanced as the ratio in the diffusion layer depth Xj becomes the smaller than 1.

### Second Example

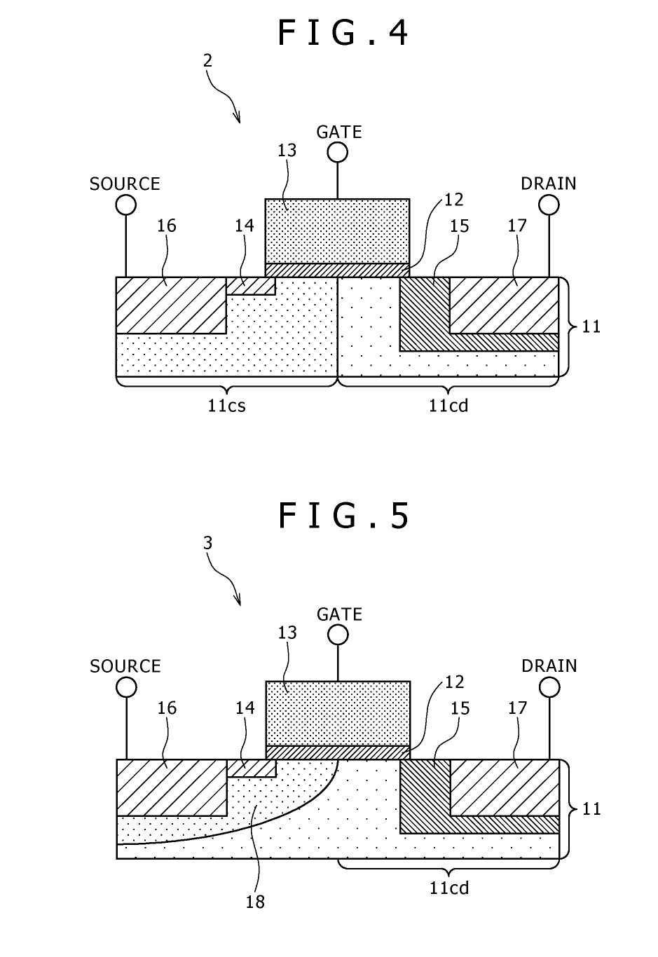

Next, a second example of the semiconductor device according to the first embodiment of the present invention will be described in detail hereinafter with reference to a schematic structural cross sectional view of FIG. 4.

As shown in FIG. 4, the gate electrode 13 is formed on the semiconductor substrate 11 through the gate insulating film 12. The silicon semiconductor substrate, for example, is used as the semiconductor substrate 11 described above. Alternatively, the SOI substrate or the like may be used as the semiconductor substrate 11 described above.

A channel region 11cs on the source side of the semiconductor substrate 11 is formed at a higher impurity concentration than that of a channel region 11cd on the drain side of the semiconductor substrate 11. For example, the impurity concentration of the channel region 11cd on the drain side of the semiconductor substrate 11 is set at a substrate impurity concentration. For example, the impurity concentration of the channel region 11cd on the drain side of the semiconductor substrate 11 is set at about 1×10¹⁴/cm³ to about 1×10¹⁵/cm³.

Also, in the case of the NMOS transistor, the channel region 11cs on the source side of the semiconductor substrate 11, for example, is doped with either boron or indium at an impurity concentration of 1×10¹⁹/cm³ or less. Preferably, indium having a smaller diffusion coefficient is used in the doping process.

On the other hand, in the case of the PMOS transistor, the channel region 11cs on the source side of the semiconductor substrate 11, for example, is doped with either arsenic or phosphorus at an impurity concentration of 1×10¹⁹/cm³ or less. Preferably, arsenic having a smaller diffusion coefficient is used in the doping process.

The extension region 14 is formed in a portion of the semiconductor substrate 11 on the source side of the gate electrode 13.

In the case of the NMOS transistor, the extension region 14 is formed in the form of an impurity region, for example, formed by diffusing thereinto either arsenic or phosphorus. For example, either an arsenic concentration or a phosphorus concentration in the extension region 14 is in the range of about 1×10¹⁸/cm³ to about 5×10²¹/cm³.

On the other hand, in the case of the PMOS transistor, the extension region 14 is formed in the form of an impurity region, for example, formed by diffusing thereinto boron (the extension region 14 is doped with boron in the form of boron difluoride). For example, a boron concentration in the extension region 14 is in the range of about 1×10¹⁸/cm³ to about 5×10²¹/cm³.

The source region 16 is formed in a portion of the semiconductor substrate 11 on the source side of the gate electrode 13 through the extension region 14.

In the case of the NMOS transistor, the source region 16 is formed in the form of an impurity region, for example, formed by diffusing thereinto either arsenic or phosphorus. For example, either an arsenic concentration or a phosphorus concentration in the source region 16 is in the range of about 1×10¹⁸/cm³ to about 5×10²¹/cm³.

Arsenic is preferably used as the impurity forming the extension region 14. The reason for this is because the impurity having a smaller diffusion coefficient is preferably used and thus arsenic having a smaller diffusion coefficient than that of phosphorus is preferably used since the extension region 14 is shallowly formed.

On the other hand, in the case of the PMOS transistor, the source region 16 is formed in the form of an impurity region, for example, formed by diffusing thereinto boron (the source region 16 is doped with boron in the form of boron difluoride). For example, a boron concentration in the source region 16 is in the range of about 1×10¹⁸/cm³ to about 5×10²¹/cm³.

In addition, the LDD region 15 is formed in a portion of the semiconductor substrate 11 on the drain side of the gate electrode 13.

In the case of the NMOS transistor, the LDD region 15 is formed in the form of an impurity region, for example, formed by diffusing thereinto either arsenic or phosphorus. For example, phosphorus is preferably used and a phosphorus concentration is lower than that of the extension region 14. Thus, the phosphorus concentration in the LDD region 15, for example, is selected from the range of 1×10¹⁶ /cm³ to 1×10²⁰/cm³.

As has been described, the reason that phosphorus is used as the impurity forming the LDD region 15 is because the effect for weakening an electric field is larger in phosphorus than in arsenic.

On the other hand, in the case of the PMOS transistor, the LDD region 15 is formed in the form of an impurity region, for example, formed by diffusing thereinto boron (the LDD region 15 is doped with boron in the form of boron difluoride). A phosphorus concentration in the LDD region 15 is lower than that in the extension region 14, and, for example, is selected from the range of 1×10¹⁷/cm³ to 5×10²⁰/cm³.

The drain region 17 is formed in a portion of the semiconductor substrate 11 on the drain side of the gate electrode 13 through the LDD region 15.

In the case of the NMOS transistor, the drain region 17 is formed in the form of an impurity region, for example, formed by diffusing thereinto either arsenic or phosphorus. For example, either an arsenic concentration or a phosphorus concentration in the drain region 17 is in the range of about 1×10¹⁸/cm³ to about 5×10²¹/cm³.

On the other hand, in the case of the PMOS transistor, the drain region 17 is formed in the form of an impurity region, for example, formed by diffusing thereinto boron (the drain region 17 is doped with boron in the form of boron difluoride). For example, a boron concentration in the drain region 17 is in the range of about 1×10¹⁸/cm³ to about 5×10²¹/cm³.

The semiconductor device 2 of the second example is structured in the form of the MOS transistor in the manner as described above.

In the semiconductor device 2 of the second example described above, the hot carrier current is suppressed by the LDD region 15, the short channel effect is suppressed by the extension region 14 shallower than the LDD region 15, and gds between the source region 16 and the drain region 17 is improved. In addition, since the short channel effect is suppressed, the channel region can be formed at the low impurity concentration, and thus gmb can be prevented from being made worse. In addition, since the extension region 14 is formed at the higher impurity concentration than that of the LDD region 15, the parasitic resistance is hardly increased and thus reduction in gm is also less.

Therefore, there is obtained an advantage that since the reduction in gm showing the trade-off relationship with gds and gmb is less and thus gds and gmb can be maintained, the high performance promotion of the MOS transistor can be realized. In addition, using the semiconductor device 2 of the second example described above in the source follower circuit makes it possible to enhance the gain of the source follower circuit.

Moreover, the channel region 11cs on the source side of the semiconductor substrate 11 is formed at the higher impurity concentration than that of the channel region 11cd on the drain side of the semiconductor substrate 11. Thus, the impurity concentration, of the channel region 11cd on the drain side of the semiconductor substrate 11, set at the substrate concentration is low. As a result, the electric field on the drain side of the semiconductor substrate 11 can be relaxed, thereby making it possible to suppress the generation of the hot carrier current.

In addition, in the case of the NMOS transistor, indium which hardly diffuses is used as the impurity forming the channel region 11cs on the source side of the semiconductor substrate 11, whereby indium can be prevented from diffusing into the channel region 11cd on the drain side of the semiconductor substrate 11. Therefore, the electric field on the drain side of the semiconductor substrate 11 can be relaxed, thereby making it possible to suppress the generation of the hot carrier current.

### Third Example

Next, a third example of the semiconductor device according to the first embodiment of the present invention will be described in detail hereinafter with reference to a schematic structural cross sectional view of FIG. 5.

As shown in FIG. 5, the gate electrode 13 is formed on the semiconductor substrate 11 through the gate insulating film 12. The silicon semiconductor substrate, for example, is used as the semiconductor substrate 11 described above. Alternatively, the SOI substrate or the like may be used as the semiconductor substrate 11 described above.

The extension region 14 is formed in a portion of the semiconductor substrate 11 on the source side of the gate electrode 13.

In the case of the NMOS transistor, the extension region 14 is formed in the form of an impurity region, for example, formed by diffusing thereinto either arsenic or phosphorus. For example, either an arsenic concentration or a phosphorus concentration in the extension region 14 is in the range of about 1×10¹⁸/cm³ to about 5×10²¹/cm³.

On the other hand, in the case of the PMOS transistor, the extension region 14 is formed in the form of an impurity region, for example, formed by diffusing thereinto boron (the extension region 14 is doped with boron in the form of boron difluoride). For example, a boron concentration in the extension region 14 is in the range of about 1×10¹⁸/cm³ to about 5×10²¹/cm³.

The source region 16 is formed in a portion of the semiconductor substrate 11 on the source side of the gate electrode 13 through the extension region 14.

In the case of the NMOS transistor, the source region 16 is formed in the form of an impurity region, for example, formed by diffusing thereinto either arsenic or phosphorus. For example, either an arsenic concentration or a phosphorus concentration in the source region 16 is in the range of about 1×10¹⁸/cm³ to about 5×10²¹/cm³.

Arsenic is preferably used as the impurity forming the extension region 14. The reason for this is because the impurity having a smaller diffusion coefficient is preferably used and thus arsenic having a smaller diffusion coefficient than that of phosphorus is preferably used since the extension region 14 is shallowly formed.

On the other hand, in the case of the PMOS transistor, the source region 16 is formed in the form of an impurity region, for example, formed by diffusing thereinto boron (the source region 16 is doped with boron in the form of boron difluoride). For example, a boron concentration in the source region 16 is in the range of about 1×10¹⁸/cm³ to about 5×10²¹/cm³.

In addition, the LDD region 15 is formed in a portion of the semiconductor substrate 11 on the drain side of the gate electrode 13.

In the case of the NMOS transistor, the LDD region 15 is formed in the form of an impurity region, for example, formed by diffusing thereinto either arsenic or phosphorus. For example, phosphorus is preferably used and a phosphorus concentration is lower than that of the extension region 14. Thus, the phosphorus concentration in the LDD region 15, for example, is selected from the range of 1×10¹⁶ /cm³ to 1×10²⁰/cm³.

As has been described, the reason that phosphorus is used as the impurity forming the LDD region 15 is because the effect for weakening an electric field is larger in phosphorus than in arsenic.

On the other hand, in the case of the PMOS transistor, the LDD region 15 is formed in the form of an impurity region, for example, formed by diffusing thereinto boron (the LDD region 15 is doped with boron in the form of boron difluoride). A boron concentration in the LDD region 15 is lower than that in the extension region 14, and, for example, is selected from the range of 1×10¹⁷/cm³ to 5×10²⁰/cm³.

The drain region 17 is formed in a portion of the semiconductor substrate 11 on the drain side of the gate electrode 13 through the LDD region 15.

In the case of the NMOS transistor, the drain region 17 is formed in the form of an impurity region, for example, formed by diffusing thereinto either arsenic or phosphorus. For example, either an arsenic concentration or a phosphorus concentration in the drain region 17 is in the range of about 1×10¹⁸/cm³ to about 5×10²¹/cm³.

On the other hand, in the case of the PMOS transistor, the drain region 17 is formed in the form of an impurity region, for example, formed by diffusing thereinto boron (the drain region 17 is doped with boron in the form of boron difluoride). For example, a boron concentration in the drain region 17 is in the range of about 1×10¹⁸/cm³ to about 5×10²¹/cm³.

Moreover, the source side of the semiconductor substrate 11 has a pocket diffusion region 18. The pocket diffusion region 18 includes the extension region 14 and the source region 16, and has a higher impurity concentration than that of the channel region 11cd on the drain side of the gate electrode 13. For example, the impurity concentration of the channel region 11cd on the drain side of the gate electrode 13 is set at the substrate concentration. For example, the impurity concentration of the channel region 11cd on the drain side of the gate electrode 13 is in the range of about 1×10¹⁴/cm³ to about 1×10¹⁵/cm³.

Also, in the case of the NMOS transistor, the pocket diffusion region 18, for example, is doped with either boron or indium at an impurity concentration of 1×10¹⁹/cm³ or less. Preferably, indium having a smaller diffusion coefficient is used in the doping process.

On the other hand, in the case of the PMOS transistor, the pocket diffusion region 18, for example, is doped with either arsenic or phosphorus at an impurity concentration of 1×10¹⁹/cm³ or less. Preferably, arsenic having a smaller diffusion coefficient is used in the doping process.

The semiconductor device 3 of the third example is structured in the form of the MOS transistor in the manner as described above.

In the semiconductor device 3 of the third example described above, the hot carrier current is suppressed by the LDD region 15, the short channel effect is suppressed by the extension region 14 shallower than the LDD region 15, and gds between the source region 16 and the drain region 17 is improved. In addition, since the short channel effect is suppressed, the channel region can be formed at the low impurity concentration, and thus gmb can be prevented from being made worse. In addition, since the extension region 14 is formed at the higher impurity concentration than that of the LDD region 15, the parasitic resistance is hardly increased and thus reduction in gm is also less.

Therefore, there is obtained an advantage that since the reduction in gm showing the trade-off relationship with gds and gmb is less and thus gds and gmb can be maintained, the high performance promotion of the MOS transistor can be realized. As a result, using the semiconductor device 3 of the third example described above in the source follower circuit makes it possible to enhance the gain of the source follower circuit.

Moreover, the pocket diffusion layer 18 of the semiconductor substrate 11 is formed at the higher impurity concentration than that of the channel region on the drain side of the semiconductor substrate 11. Thus, the impurity concentration, of the channel region 11cd on the drain side of the semiconductor substrate 11, set at the substrate concentration is low. As a result, the electric field, on the drain side of the semiconductor substrate 11 can be relaxed, thereby making it possible to suppress the generation of the hot carrier current.

### 2. Second Embodiment

A method of manufacturing the semiconductor device according to a second embodiment of the present invention includes the steps of: forming the gate electrode on the semiconductor substrate through the gate insulating film; forming the LDD region in the semiconductor substrate on the drain side of the gate electrode; forming the extension region in the semiconductor substrate on the source side of the gate electrode; forming the source region in the semiconductor substrate on the source side of the gate electrode through the extension region, and forming the drain region in the semiconductor substrate on the drain side of the gate electrode through the LDD region; and forming the extension region at a higher impurity concentration than that of the LDD region so as to be shallower than the LDD region.

### First Example

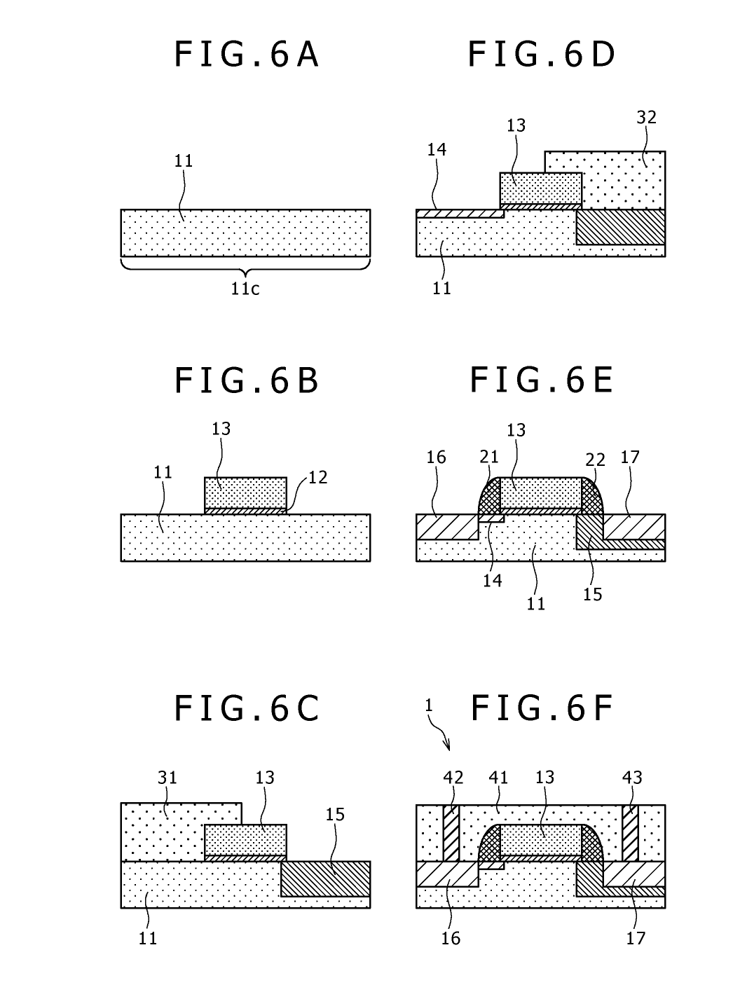

A first example of the method of manufacturing the semiconductor device according to the second embodiment of the present invention will be described in detail hereinafter with reference to cross sectional views showing respective manufacturing processes of FIGS. 6A to 6F.

As shown in FIG. 6A, channel ion implantation for formation of the channel region 11c is carried out for the semiconductor substrate 11. The silicon semiconductor substrate, for example, is used as the semiconductor substrate 11. Alternatively, the SOI substrate or the like may be used as the semiconductor substrate 11.

In the case of the NMOS transistor, in the channel ion implantation process, either boron or indium ions are implanted into the semiconductor substrate 11. When the boron ions are implanted into the semiconductor substrate 11, an implantation energy is set in the range of 3 to 100 keV, and a dosage is set at 5×10¹³/cm² or less. On the other hand, when the indium ions are implanted into the semiconductor substrate 11, the implantation energy is set in the range of 15 to 2,000 keV, and a dosage is set at 5×10¹³/cm² or less. Preferably, indium having a smaller diffusion coefficient is used in the channel ion implantation process.

On the other hand, in the case of the PMOS transistor, in the channel ion implantation process, either arsenic or phosphorus ions are implanted into the semiconductor substrate 11.

When the arsenic ions are implanted into the semiconductor substrate 11, the implantation energy is set in the range of 20 to 500 keV, and a dosage is set at 5×10¹³/cm² or less. On the other hand, when the phosphorus ions are implanted into the semiconductor substrate 11, the implantation energy is set in the range of 10 to 300 keV, and a dosage is set at 5×10¹³/cm² or less. Preferably, arsenic having a smaller diffusion coefficient is used in the channel ion implantation process.

In addition, the channel ion implantation may not be carried out depending on the substrate concentrations. For example, the channel ion implantation may not be carried out when the substrate concentration becomes the concentration after completion of the channel ion implantation.

Next, as shown in FIG. 6B, the gate electrode 13 is formed on the semiconductor substrate 11 through the gate insulating film 12. For example, the gate insulating film 12 is formed in the form of a thermal oxide film on the semiconductor substrate 11. Next, after a gate electrode formation film is deposited on the gate insulating film 12, the gate electrode formation film is patterned by utilizing a lithography technique using a resist mask (not shown) and an etching technique, thereby forming the gate electrode 13.

After that, the resist mask is removed.

Next, as shown in FIG. 6C, after a resist is applied to the semiconductor substrate 11, a resist mask 31 covering the source side of the semiconductor substrate 11 is formed by utilizing the lithography technique. After that, impurity ions are implanted into the drain side of the semiconductor substrate 11 by using both the resist mask 31 and the gate electrode 13 as an ion implantation mask, thereby forming the LDD region 15.

In the case of the NMOS transistor, for example, either arsenic or phosphorus ions are implanted into the drain side of the semiconductor substrate 11, thereby forming the LDD region 15. Preferably, the phosphorus ions are implanted into the drain side of the semiconductor substrate 11.

When the phosphorus ions are implanted into the drain side of the semiconductor substrate 11, an implantation energy is set in the range of 10 to 60 keV, and a dosage is set in the range of 1×10¹²/cm² to 5×10¹⁴/cm².

The reason that phosphorus is used as the impurity forming the LDD region 15 in the manner as described above is because the effect for weakening an electric field is larger in phosphorus than in arsenic.

On the other hand, in the case of the PMOS transistor, for example, boron difluoride ions are implanted into the drain side of the semiconductor substrate 11, thereby forming the LDD region 15. When the boron difluoride ions are implanted into the drain side of the semiconductor substrate 11, an implantation energy is set in the range of 5 to 100 keV, and a dosage is set in the range of 1×10¹²/cm² to 5×10¹⁴/cm².

After that, the resist mask 31 described above is removed. FIG. 6C shows a state right before removal of the resist mask 31.

Next, as shown in FIG. 6D, after a resist is applied to the semiconductor substrate 11, a resist mask 32 covering the drain side of the semiconductor substrate 11 is formed by utilizing the lithography technique. Impurity ions are implanted into the source side of the semiconductor substrate 11 by using both the resist mask 32 and the gate electrode 13 as an ion implantation mask, thereby forming the extension region 14. Here, the extension region 14 is shallower than the LDD region 15, and is higher in impurity concentration than the LDD region 15.

In the case of the NMOS transistor, for example, either arsenic or phosphorus ions are implanted into the source side of the semiconductor substrate 11, thereby forming the extension region 14. Preferably, the arsenic ions are implanted into the source side of the semiconductor substrate 11.

When the arsenic ions are implanted into the source side of the semiconductor substrate 11, an implantation energy is set in the range of 5 to 100 keV, and a dosage is set in the range of 1×10¹³/cm² to 5×10¹⁵/cm².

The reason that arsenic is used as the impurity forming the extension region 14 in the manner as described above is because a shallow junction is more readily formed with arsenic than with phosphorus since a diffusion coefficient is smaller in arsenic than in phosphorus.

On the other hand, in the case of the PMOS transistor, for example, boron difluoride ions are implanted into the source side of the semiconductor substrate 11, thereby forming the extension region 14. When the boron difluoride ions are implanted into the source side of the semiconductor substrate 11, an implantation energy is set in the range of 5 to 100 keV, and a dosage is set in the range of 1×10¹³/cm² to 5×10¹⁵/cm².

After that, the resist mask 32 described above is removed. FIG. 6D shows a state right before removal of the resist mask 32.

Next, as shown in FIG. 6E, sidewall insulating films 21 and 22 are formed on both sidewalls of the gate electrode 13, respectively.

Next, impurity ions are implanted into the semiconductor substrate 11 by using both the gate electrode 13, and the sidewall insulating films 21 and 22 as an ion implantation mask. As a result, the source region 16 is formed in a portion of the semiconductor substrate 11 on the source side of the gate electrode 13 through the extension region 14. In addition, the drain region 17 is formed in a portion of the semiconductor substrate 11 on the drain side of the gate electrode 13 through the LDD region 15.

In the case of the NMOS transistor, for example, either arsenic or phosphorus ions are implanted into the portions of the semiconductor substrate 11 on the source side and the drain side of the gate electrode 13 through the extension region 14 and the LDD region 15, thereby forming the source region 16 and the drain region 17, respectively. Preferably, the arsenic ions having a smaller diffusion coefficient are implanted into the portions of the semiconductor substrate 11 on the source side and the drain side of the gate electrode 13 through the extension region 14 and the LDD region 15.

When the arsenic ions are implanted into the portions of the semiconductor substrate 11 on the source side and the drain side of the gate electrode 13 through the extension region 14 and the LDD region 15, an implantation energy is set in the range of 5 to 100 keV, and a dosage is set in the range of 1×10¹³/cm² to 5×10¹⁵/cm².

On the other hand, in the case of the PMOS transistor, for example, boron difluoride ions are implanted into the portion of the semiconductor substrate 11 on the source side of the gate electrode through the extension region 14, thereby forming the source region 16. When the boron difluoride ions are implanted into the portion of the semiconductor substrate 11 on the source side of the gate electrode through the extension region 14, the implantation energy is set in the range of 5 to 100 keV, and the dosage is set in the range of 1×10¹³/cm² to 5×10¹⁵/cm².

Next, as shown in FIG. 6F, after an interlayer insulating film 41 covering the gate electrode 13, the sidewall insulating films 21 and 22, the source region 16, the drain region 17, and the like is formed, contact portions 42 and 43 communicating with the source region 16 and the drain region 17, respectively, are formed.

The semiconductor device 1 is formed in the form of the MOS transistor in accordance with the first example of the manufacturing method of the second embodiment.

In the semiconductor device 1 formed in accordance with the first example of the manufacturing method of the second embodiment, the hot carrier current is suppressed by forming the LDD region 15, the short channel effect is suppressed by forming the extension region 14 shallower than the LDD region 15, and thus gds between the source region 16 and the drain region 17 is improved. In addition, since the short channel effect is suppressed, the channel region 11 can be formed at the low impurity concentration, and thus gmb can be prevented from being made worse. In addition, since the extension region 14 is formed at the higher impurity concentration than that of the LDD region 15, the parasitic resistance is hardly increased and thus reduction in gm is also less.

Therefore, there is obtained an advantage that since the reduction in gm showing the trade-off relationship with gds and gmb is less and thus gds and gmb can be maintained, the high performance promotion of the MOS transistor can be realized. As a result, using the semiconductor device 1 described above in the source follower circuit makes it possible to enhance the gain of the source follower circuit.

### Second Example

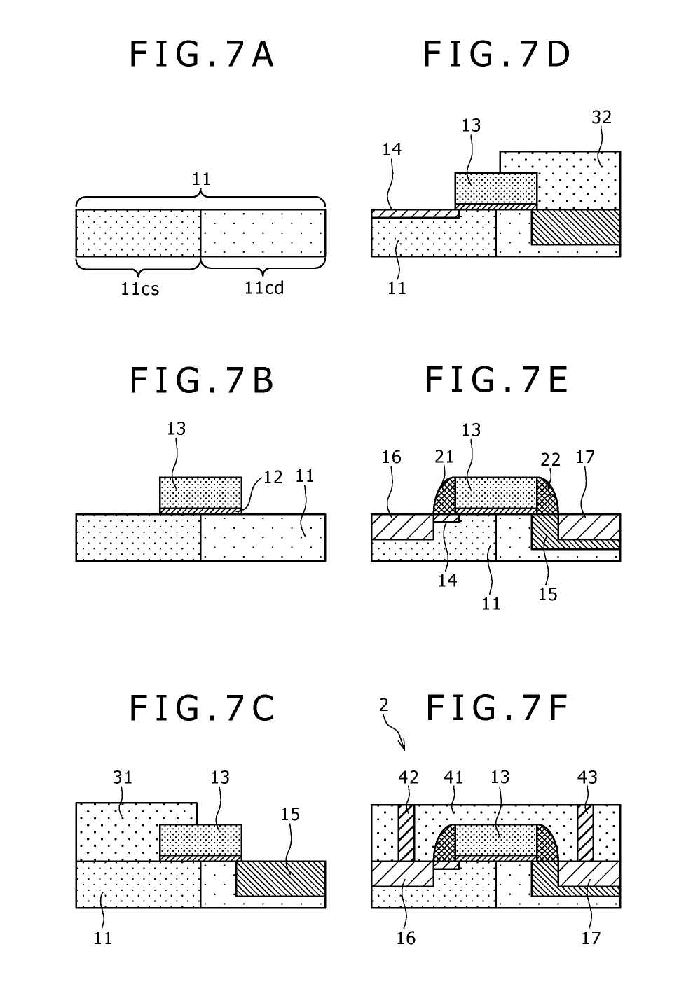

A second example of the method of manufacturing the semiconductor device according to the second embodiment of the present invention will be described in detail hereinafter with reference to cross sectional views showing respective manufacturing processes of FIGS. 7A to 7F.

As shown in FIG. 7A, after a resist is applied to the semiconductor substrate 11, a resist mask 33 covering the drain side of the semiconductor substrate 11 is formed on the semiconductor substrate 11 by utilizing the lithography technique. The silicon semiconductor substrate, for example, is used as the semiconductor substrate 11. Alternatively, the SOI substrate or the like may be used as the semiconductor substrate 11.

Next, impurity ions are implanted into a portion of the semiconductor substrate 11 on the source side by using the resist mask 33 as an ion implantation mask, thereby forming the channel region 11cs. As a result, the channel region 11cs on the source side of the semiconductor substrate 11 is formed at the higher impurity concentration than that of the channel region 11cd on the drain side of the semiconductor substrate 11.

In the case of the NMOS transistor, in the channel ion implantation process, either boron or indium ions are implanted into the semiconductor substrate 11. When the boron ions are implanted into the semiconductor substrate 11, an implantation energy is set in the range of 3 to 100 keV, and a dosage is set at 5×10¹³/cm² or less. On the other hand, when the indium ions are implanted into the semiconductor substrate 11, the implantation energy is set in the range of 15 to 2,000 keV, and the dosage is set as 5×10¹³/cm² or less. Preferably, indium having a smaller diffusion coefficient is used in the channel ion implantation process.

On the other hand, in the case of the PMOS transistor, in the channel ion implantation process, either arsenic or phosphorus ions are implanted into the semiconductor substrate 11.

When the arsenic ions are implanted into the semiconductor substrate 11, the implantation energy is set in the range of 20 to 500 keV, and a dosage is set at 5×10¹³/m or less. On the other hand, the phosphorus ions are implanted into the semiconductor substrate 11, the implantation energy is set in the range of 10 to 300 keV, and the dosage is set at 5×10¹³/cm² or less. Preferably, arsenic having a smaller diffusion coefficient is used in the channel ion implantation process.

It is noted that the impurity concentration of the channel region 11cd on the drain side of the semiconductor substrate 11 is set at the substrate concentration. For example, the impurity concentration of the channel region 11cd on the drain side of the semiconductor substrate 11 is set in the range of about 1×10¹⁴/cm³ to about 1×10¹⁵/cm³.

Next, as shown in FIG. 7B, the gate electrode 13 is formed on the semiconductor substrate 11 through the gate insulating film 12. For example, the gate insulating film 12 is formed in the form of a thermal oxide film on the semiconductor substrate 11. Next, after a gate electrode formation film is deposited on the gate insulating film 12, the gate electrode formation film is patterned by utilizing the lithography technique using a resist mask (not shown) and the etching technique, thereby forming the gate electrode 13.

After that, the resist mask is removed.

Next, as shown in FIG. 7C, after a resist is applied to the semiconductor substrate 11, the resist mask 31 covering the source side of the semiconductor substrate 11 is formed by utilizing the lithography technique. After that, impurity ions are implanted into the drain side of the semiconductor substrate 11 by using both the resist mask 31 and the gate electrode 13 as an ion implantation mask, thereby forming the LDD region 15.

In the case of the NMOS transistor, for example, either arsenic or phosphorus ions are implanted into the drain side of the semiconductor substrate 11, thereby forming the LDD region 15. Preferably, the phosphorus ions are implanted into the drain side of the semiconductor substrate 11.

When the phosphorus ions are implanted into the drain side of the semiconductor substrate 11, an implantation energy is set in the range of 10 to 60 keV, and a dosage is set in the range of 1×10¹²/cm² to 5×10¹⁴/cm².

The reason that phosphorus is used as the impurity forming the LDD region 15 in the manner as described above is because the effect for weakening an electric field is larger in phosphorus than in arsenic.

On the other hand, in the case of the PMOS transistor, for example, boron difluoride ions are implanted into the drain side of the semiconductor substrate 11, thereby forming the LDD region 15. When the boron difluoride ions are implanted into the drain side of the semiconductor substrate 11, the implantation energy is set in the range of 5 to 100 keV, and the dosage is set in the range of 1×10¹²/cm² to 5×10¹⁴/cm².

After that, the resist mask 31 described above is removed. FIG. 6C shows a state right before removal of the resist mask 31.

Next, as shown in FIG. 7D, after a resist is applied to the semiconductor substrate 11, a resist mask 32 covering the drain side of the semiconductor substrate 11 is formed by utilizing the lithography technique. Impurity ions are implanted into the source side of the semiconductor substrate 11 by using both the resist mask 32 and the gate electrode 13 as an ion implantation mask, thereby forming the extension region 14. Here, the extension region 14 is shallower than the LDD region 15, and is higher in impurity concentration than the LDD region 15.

In the case of the NMOS transistor, for example, either arsenic or phosphorus ions are implanted into the source side of the semiconductor substrate 11, thereby forming the extension region 14. Preferably, the arsenic ions are implanted into the source side of the semiconductor substrate 11.

When the arsenic ions are implanted into the source side of the semiconductor substrate 11, an implantation energy is set in the range of 5 to 100 keV, and a dosage is set in the range of 1×10¹³/cm² to 5×10¹⁵/cm².

The reason that arsenic is used as the impurity forming the extension region 14 in the manner as described above is because a shallow junction is more readily formed with arsenic than with phosphorus since a diffusion coefficient is smaller in arsenic than in phosphorus.

On the other hand, in the case of the PMOS transistor, for example, boron difluoride ions are implanted into the source side of the semiconductor substrate 11, thereby forming the extension region 14. When the boron difluoride ions are implanted into the source side of the semiconductor substrate 11, the implantation energy is set in the range of 5 to 100 keV, and the dosage is set in the range of 1×10¹³/cm² to 5×10¹⁵/cm².

After that, the resist mask 32 described above is removed. FIG. 7D shows a state right before removal of the resist mask 32.

Next, as shown in FIG. 7E, the sidewall insulating films 21 and 22 are formed on both the sidewalls of the gate electrode 13, respectively.

Next, impurity ions are implanted into the semiconductor substrate 11 by using both the gate electrode 13, and the sidewall insulating films 21 and 22 as an ion implantation mask. As a result, the source region 16 is formed in a portion of the semiconductor substrate 11 on the source side of the gate electrode 13 through the extension region 14. In addition, the drain region 17 is formed in a portion of the semiconductor substrate 11 on the drain side of the gate electrode 13 through the LDD region 15.

In the case of the NMOS transistor, for example, either arsenic or phosphorus ions are implanted into the portions of the semiconductor substrate 11 on the source side and the drain side of the gate electrode 13 through the extension region 14 and the LDD region 15, thereby forming the source region 16 and the drain region 17, respectively. Preferably, the arsenic ions having a smaller diffusion coefficient are implanted into the portions of the semiconductor substrate 11 on the source side and the drain side of the gate electrode 13 through the extension region 14 and the LDD region 15.

When the arsenic ions are implanted into the portions of the semiconductor substrate 11 on the source side and the drain side of the gate electrode 13 through the extension region 14 and the LDD region 15, an implantation energy is set in the range of 5 to 100 keV, and a dosage is set in the range of 1×10¹³/cm² to 5×10¹⁵/cm².

On the other hand, in the case of the PMOS transistor, for example, boron difluoride ions are implanted into the portion of the semiconductor substrate 11 on the source side of the gate electrode 13 through the extension region 14, thereby forming the source region 16. When the boron difluoride ions are implanted into the portion of the semiconductor substrate 11 on the source side of the gate electrode 13 through the extension region 14, the implantation energy is set in the range of 5 to 100 keV, and the dosage is set in the range of 1×10¹³/cm² to 5×10¹⁵/cm².

Next, as shown in FIG. 7F, after the interlayer insulating film 41 covering the gate electrode 13, the sidewall insulating films 21 and 22, the source region 16, the drain region 17, and the like is formed, the contact portions 42 and 43 communicating with the source region 16 and the drain region 17, respectively, are formed.

The semiconductor device 2 is formed in the form of the MOS transistor in accordance with the second example of the manufacturing method of the second embodiment.

In the semiconductor device 2 formed in accordance with the second example of the manufacturing method of the second embodiment, the hot carrier current is suppressed by forming the LDD region 15, the short channel effect is suppressed by forming the extension region 14 shallower than the LDD region 15, and thus gds between the source region 16 and the drain region 17 is improved. In addition, since the short channel effect is suppressed, the channel region can be formed at the low impurity concentration, and thus gmb can be prevented from being made worse. In addition, since the extension region 14 is formed at the higher concentration than that of the LDD region 15, the parasitic resistance is hardly increased and thus reduction in gm is also less.

Therefore, there is obtained an advantage that since the reduction in gm showing the trade-off relationship with gds and gmb is less and thus gds and gmb can be maintained, the high performance promotion of the MOS transistor can be realized. As a result, using the semiconductor device 2 described above in the source follower circuit makes it possible to enhance the gain of the source follower circuit.

Moreover, the channel region 11cs on the source side of the semiconductor substrate 11 is formed at the higher impurity concentration than that of the channel region 11cd on the drain side of the semiconductor substrate 11. Thus, the impurity concentration, of the channel region 11cd on the drain side of the semiconductor substrate 11, set at the substrate concentration is low. As a result, the electric field on the drain side of the semiconductor substrate 11 can be relaxed, thereby making it possible to suppress the generation of the hot carrier current.

In addition, in the case of the NMOS transistor, indium which hardly diffuses is used as the impurity forming the channel region 11cs on the source side of the semiconductor substrate 11, whereby indium can be prevented from diffusing into the channel region 11cd on the drain side of the semiconductor substrate 11. Therefore, the electric field, on the drain side of the semiconductor substrate 11 can be relaxed, thereby making it possible to suppress the generation of the hot carrier current.

### Third Example

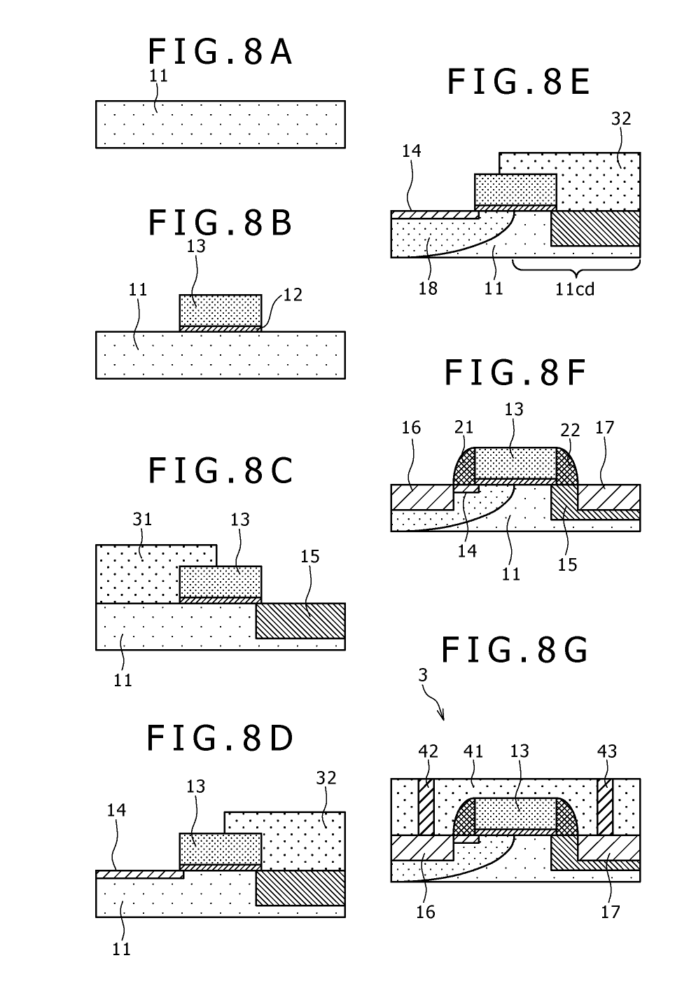

A third example of the method of manufacturing the semiconductor device according to the second embodiment of the present invention will be described in detail hereinafter with reference to cross sectional views showing respective manufacturing processes of FIGS. 8A to 8G.

As shown in FIG. 8A, the semiconductor substrate 11 is firstly prepared. The silicon semiconductor substrate, for example, is used as the semiconductor substrate 11. Alternatively, the SOI substrate or the like may be used as the semiconductor substrate 11.

Next, as shown in FIG. 8B, the gate electrode 13 is formed on the semiconductor substrate 11 through the gate insulating film 12. For example, the gate insulating film 12 is formed in the form of a thermal oxide film on the semiconductor substrate 11. Next, after the gate electrode formation film is deposited on the gate insulating film 12, the gate electrode formation film is patterned by utilizing the lithography technique using a resist mask (not shown) and the etching technique, thereby forming the gate electrode 13.

After that, the resist mask is removed.

Next, as shown in FIG. 8C, after a resist is applied to the semiconductor substrate 11, the resist mask 31 covering the source side of the semiconductor substrate 11 is formed by utilizing the lithography technique. After that, impurity ions are implanted into the drain side of the semiconductor substrate 11 by using both the resist mask 31 and the gate electrode 13 as an ion implantation mask, thereby forming the LDD region 15.

In the case of the NMOS transistor, for example, either arsenic or phosphorus ions are implanted into the drain side of the semiconductor substrate 11, thereby forming the LDD region 15. Preferably, the phosphorus ions are implanted into the drain side of the semiconductor substrate 11.

When the phosphorus ions are implanted into the drain side of the semiconductor substrate 11, an implantation energy is set in the range of 10 to 60 keV, and a dosage is set in the range of 1×10¹²/cm² to 5×10¹⁴/cm².

The reason that phosphorus is used as the impurity forming the LDD region 15 in the manner as described above is because the effect for weakening an electric field is larger in phosphorus than in arsenic.

On the other hand, in the case of the PMOS transistor, for example, boron difluoride ions are implanted into the drain side of the semiconductor substrate 11, thereby forming the LDD region 15. When the boron difluoride ions are implanted into the drain side of the semiconductor substrate 11, the implantation energy is set in the range of 5 to 100 keV, and the dosage is set in the range of 1×10¹²/cm² to 5×10¹⁴/cm².

After that, the resist mask 31 described above is removed. FIG. 8C shows a state right before removal of the resist mask 31.

Next, as shown in FIG. 8D, after a resist is applied to the semiconductor substrate 11, a resist mask 32 covering the drain side of the semiconductor substrate 11 is formed by utilizing the lithography technique. Impurity ions are implanted into the source side of the semiconductor substrate 11 by using both the resist mask 32 and the gate electrode 13 as an ion implantation mask, thereby forming the extension region 14. Here, the extension region 14 is shallower than the LDD region 15, and is higher in impurity concentration than the LDD region 15.

In the case of the NMOS transistor, for example, either arsenic or phosphorus ions are implanted into the source side of the semiconductor substrate 11, thereby forming the extension region 14. Preferably, the arsenic ions are implanted into the source side of the semiconductor substrate 11.

When the arsenic ions are implanted into the source side of the semiconductor substrate 11, an implantation energy is set in the range of 5 to 100 keV, and a dosage is set in the range of 1×10¹³/cm² to 5×10¹⁵/cm².

The reason that arsenic is used as the impurity forming the extension region 14 in the manner as described above is because a shallow junction is more readily formed with arsenic than with phosphorus since a diffusion coefficient is smaller in arsenic than in phosphorus.

On the other hand, in the case of the PMOS transistor, for example, boron difluoride ions are implanted into the source side of the semiconductor substrate 11, thereby forming the extension region 14. When the boron difluoride ions are implanted into the source side of the semiconductor substrate 11, the implantation energy is set in the range of 5 to 100 keV, and the dosage is set in the range of 1×10¹³/cm² to 5×10¹⁵/cm².

Moreover, as shown in FIG. 8E, the pocket diffusion layer 18 is formed on the source side of the semiconductor substrate 11 by carrying out oblique ion implantation using the resist mask 32. In this case, the pocket diffusion layer 18 includes the extension region 14, and the source region 16 which will be formed in the subsequent process, and is higher in impurity concentration than the channel region 11cd on the drain side of the semiconductor substrate 11.

In the case of the NMOS transistor, in the oblique ion implantation process, either boron or indium ions are implanted into the semiconductor substrate 11. When the boron ions are implanted into the semiconductor substrate 11, an implantation energy is set in the range of 3 to 100 keV, and a dosage is set at 5×10¹³/cm² or less. On the other hand, when the indium ions are implanted into the semiconductor substrate 11, the implantation energy is set in the range of 15 to 2,000 keV, and the dosage is set at 5×10¹³/cm² or less. Preferably, indium having a smaller diffusion coefficient is used in the oblique ion implantation process.

On the other hand, in the case of the PMOS transistor, in the channel ion implantation process, either arsenic or phosphorus ions are implanted into the semiconductor substrate 11.

When the arsenic ions are implanted into the semiconductor substrate 11, the implantation energy is set in the range of 20 to 500 keV, and the dosage is set at 5×10¹³/cm² or less. On the other hand, when the phosphorus ions are implanted into the semiconductor substrate 11, the implantation energy is set in the range of 10 to 300 keV, and the dosage is set at 5×10¹³/cm² or less. Preferably, arsenic having a smaller diffusion coefficient is used in the oblique ion implantation.

It is noted that the impurity concentration of the channel region 11cd on the drain side of the semiconductor substrate 11 is set at the substrate concentration. For example, the impurity concentration of the channel region 11cd on the drain side of the semiconductor substrate 11 is set in the range of about 1×10¹⁴/cm³ to about 1×10¹⁵/cm³.

After that, the resist mask 32 is removed. FIG. 8E shows a state just before removal of the resist mask 32.

Next, as shown in FIG. 8F, the sidewall insulating films 21 and 22 are formed on both sidewalls of the gate electrode 13, respectively.

Next, impurity ions are implanted into the semiconductor substrate 11 by using both the gate electrode 13, and the sidewall insulating films 21 and 22 as an ion implantation mask. As a result, the source region 16 is formed in a portion of the semiconductor substrate 11 on the source side of the gate electrode 13 through the extension region 14. In addition, the drain region 17 is formed in a portion of the semiconductor substrate 11 on the drain side of the gate electrode 13 through the LDD region 15.

In the case of the NMOS transistor, for example, either arsenic or phosphorus ions are implanted into the portions of the semiconductor substrate 11 on the source side and the drain side of the gate electrode 13 through the extension region 14 and the LDD region 15, thereby forming the source region 16 and the drain region 17, respectively. Preferably, the arsenic ions having a smaller diffusion coefficient are implanted into the portions of the semiconductor substrate 11 on the source side and the drain side of the gate electrode 13 through the extension region 14 and the LDD region 15.

When the arsenic ions are implanted into the portions of the semiconductor substrate 11 on the source side and the drain side of the gate electrode 13 through the extension region 14 and the LDD region 15, an implantation energy is set in the range of 5 to 100 keV, and a dosage is set in the range of 1×10¹³/cm² to 5×10¹⁵/cm².

On the other hand, in the case of the PMOS transistor, for example, boron difluoride ions are implanted into the portion of the semiconductor substrate 11 on the source side of the gate electrode 13 through the extension region 14, thereby forming the source region 16. When the boron difluoride ions are implanted into the portion of the semiconductor substrate 11 on the source side of the gate electrode 13 through the extension region 14, the implantation energy is set in the range of 5 to 100 keV, and the dosage is set in the range of 1×10¹³/cm² to 5×10¹⁵/cm².

Next, as shown in FIG. 8G, after the interlayer insulating film 41 covering the gate electrode 13, the sidewall insulating films 21 and 22, the source region 16, the drain region 17, and the like is formed, the contact portions 42 and 43 communicating with the source region 16 and the drain region 17, respectively, are formed.

The semiconductor device 3 is formed in the form of the MOS transistor in accordance with the third example of the manufacturing method of the second embodiment.

In the semiconductor device 3 formed in accordance with the third example of the manufacturing method of the second embodiment, the hot carrier current is suppressed by forming the LDD region 15, the short channel effect is suppressed by forming the extension region 14 shallower than the LDD region 15, and thus gds between the source region 16 and the drain region 17 is improved. In addition, since the short channel effect is suppressed, the channel region can be formed at the low impurity concentration, and thus gmb can be prevented from being made worse. In addition, since the extension region 14 is formed at the higher concentration than that of the LDD region 15, the parasitic resistance is hardly increased and thus reduction in gm is also less.

Therefore, there is obtained an advantage that since the reduction in gm showing the trade-off relationship with gds and gmb is less and thus gds and gmb can be maintained, the high performance promotion of the MOS transistor can be realized. As a result, using the semiconductor device 3 described above in the source follower circuit makes it possible to enhance the gain of the source follower circuit.

Moreover, the pocket diffusion layer 18 on the source side of the semiconductor substrate 11 is formed at the higher impurity concentration than that of the channel region 11cd on the drain side of the semiconductor substrate 11. Thus, the impurity concentration, of the channel region 11cd on the drain side of the semiconductor substrate 11, set at the substrate concentration is low. As a result, the electric field, on the drain side of the semiconductor substrate 11 can be relaxed, thereby making it possible to suppress the generation of the hot carrier current.

### 3. Third Embodiment

A solid-state image pickup device according to a third embodiment of the present invention includes: a photoelectric conversion portion for subjecting an incident light to photoelectric conversion, thereby obtaining signal electric charges; and a source follower circuit for converting the signal charges read out from the photoelectric conversion portion into a voltage, thereby outputting the resulting voltage; at least one transistor of the source follower circuit including: the gate electrode formed on the semiconductor substrate through the gate insulating film; the extension region formed in the semiconductor substrate on the source side of the gate electrode; the source region formed in the semiconductor substrate on the source side of the gate electrode through the extension region; the LDD region formed in the semiconductor substrate on a drain side of the gate electrode; and the drain region formed in the semiconductor substrate on the drain side of the gate electrode through the LDD region; in which the extension region is formed at the higher impurity concentration than that of the LDD region so as to be shallower than the LDD region.

### Example

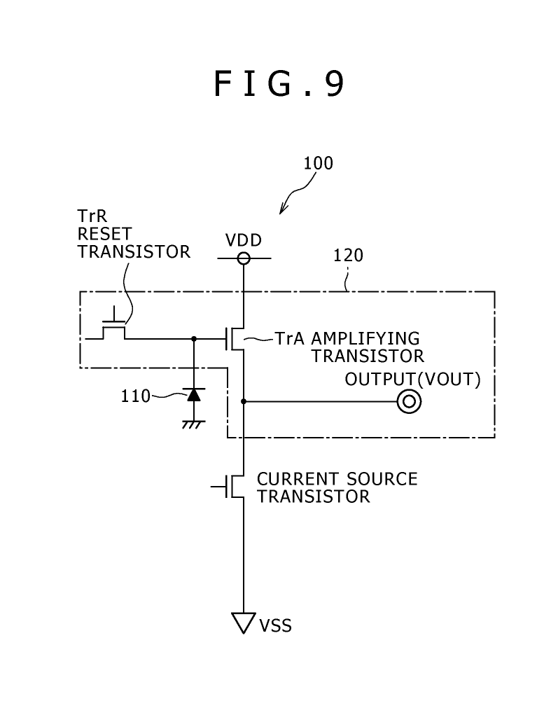

An example of the solid-state image pickup device according to the third embodiment of the present invention will be described in detail hereinafter with reference to a circuit diagram of FIG. 9.

As shown in FIG. 9, the solid-state image pickup device 100 includes a plurality of photoelectric conversion element 110, and a plurality of source follower circuits 120. In this case, a plurality of photoelectric conversion element 110 subject incident lights to photoelectric conversion, thereby obtaining signal charges, respectively. Also, a plurality of source follower circuits 120 convert the signal charges read out from a plurality of photoelectric conversion elements 110 into voltages, and output the resulting voltages, respectively. Each of the photoelectric conversion elements 110, for example, is composed of a photodiode.

Each of the source follower circuits 120, for example, includes an amplifying transistor TrA and a reset transistor TrR. One of the amplifying transistor TrA and the reset transistor TrR has the structure of any of the semiconductor devices 1 to 3 described in the first to third examples of the first embodiment, respectively. In particular, it is advantageous for enhancement of the gain of the source follower circuit 120 that the amplifying transistor TrA has the structure of any of the semiconductor devices 1 to 3 described in the first to third examples of the first embodiment, respectively.

In the solid-state image pickup device 100, the high-performance semiconductor device in which the reduction in gm is less, and thus gds and gmb are maintained, for example, is used in either the amplifying transistor TrA or the reset transistor TrR of the source follower circuit 120. For this reason, there is obtained an advantage that since the gain of the source follower circuit 120 can be enhanced, the high performance of the output circuit can be promoted.

The present application contains subject matter related to that disclosed in Japanese Priority Patent Application JP 2008-279474 filed in the Japan Patent Office on Oct. 30, 2008, the entire content of which is hereby incorporated by reference.

It should be understood by those skilled in the art that various modifications, combinations, sub-combinations and alterations may occur depending on design requirements and other factor in so far as they are within the scope of the appended claims or the equivalents thereof.

What is claimed is:

1. A semiconductor device, comprising:
gate electrode formed on a semiconductor substrate through a gate insulating film;
an extension region formed in said semiconductor substrate on a source side of said gate electrode;
a source region formed in said semiconductor substrate on the source side of said gate electrode through said extension region;
a lightly doped drain region formed in said semiconductor substrate on a drain side of said gate electrode; and
a drain region formed in said semiconductor substrate on the drain side of said gate electrode through said lightly doped drain region;
wherein,
said extension region is formed at a higher concentration than that of said lightly doped drain region so as to be shallower than said lightly doped drain region, wherein an impurity concentration of a channel region on the source side of said semiconductor substrate is higher than that of the channel region on the drain side of said semiconductor substrate.

2. A method of manufacturing a semiconductor device, comprising the steps of:
forming a gate electrode on a semiconductor substrate through a gate insulating film;
forming a lightly doped drain region in said semiconductor substrate on a drain side of said gate electrode;
forming an extension region in said semiconductor substrate on a source side of said gate electrode;
forming a source region in said semiconductor substrate on the source side of said gate electrode through said extension region, and forming a drain region in said semiconductor substrate on the drain side of said gate electrode through said lightly doped drain region; and
forming said extension region at a higher concentration than that of said lightly doped drain region so as to be shallower than said lightly doped drain region,
wherein,
before the step of forming said gate electrode, channel ion implantation is carried out for the source side of said semiconductor substrate, and an impurity concentration of the channel region on the source side is made higher than that of a channel region on the drain side.

3. A method of manufacturing a semiconductor device, comprising the steps of:
forming a gate electrode on a semiconductor substrate through a gate insulating film;
forming a lightly doped drain region in said semiconductor substrate on a drain side of said gate electrode;
forming an extension region in said semiconductor substrate on a source side of said gate electrode;
forming a source region in said semiconductor substrate on the source side of said gate electrode through said extension region, and forming a drain region in said semiconductor substrate on the drain side of said gate electrode through said lightly doped drain region; and
forming said extension region at a higher concentration than that of said lightly doped drain region so as to be shallower than said lightly doped drain region,
wherein,
after the step of forming said extension region, pocket ion implantation is carried out for the source side of said semiconductor substrate, and an impurity concentration of a channel region on the source side is made higher than that of the channel region on the drain side.

4. A solid-state image pickup device, comprising:
a photoelectric conversion portion for subjecting an incident light to photoelectric conversion, thereby obtaining signal electric charges; and
a source follower circuit for converting the signal charges read out from said photoelectric conversion portion into a voltage, thereby outputting the resulting voltage,
wherein,
(1) at least one transistor of said source follower circuit includes (a) a gate electrode formed on a semiconductor substrate through a gate insulating film, (b) an extension region formed in said semiconductor substrate on a source side of said gate electrode, (c) a source region formed in said semiconductor substrate on the source side of said gate electrode through said extension region, (d) a lightly doped drain region formed in said semiconductor substrate on a drain side of said gate electrode, and (e) a drain region formed in said semiconductor substrate on the drain side of said gate electrode through said lightly doped drain region, and
(2) said extension region is formed at a higher concentration than that of the lightly doped drain region so as to be shallower than said lightly doped drain region.
